(19) United States
(12) Patent Application Publication
(10) Pub. No.: US 2023/0198427 A1
(43) Pub. Date: Jun. 22, 2023

(54) ROTATION DRIVE MECHANISM

(71) Applicants: Seiki CHIBA, Meguro-ku, Tokyo (JP); Mikio WAKI, Sakura-shi, Tochigi (JP); ZEON CORPORATION, Chiyoda-ku, Tokyo (JP)

(72) Inventors: Seiki CHIBA, Meguro-ku, Tokyo (JP); Mikio WAKI, Sakura-shi, Tochigi (JP); Mitsugu UEJIMA, Chiyoda-ku, Tokyo (JP); Makoto TAKESHITA, Chiyoda-ku, Tokyo (JP)

(73) Assignees: ZEON CORPORATION, Chiyoda-ku, Tokyo (JP); Seiki CHIBA, Meguro-ku, Tokyo (JP); Mikio WAKI, Sakura-shi, Tochigi (JP)

(21) Appl. No.: 17/997,738

(22) PCT Filed: Mar. 24, 2021
(86) PCT No.: PCT/JP2021/012333

§ 371 Date: Nov. 2, 2022

(30) Foreign Application Priority Data
May 11, 2020 (JP) 2020-083319

(51) Int. Cl. H02N 2/04; H02N 2/00

(52) U.S. Cl. CPC H02N 2/046; H02N 2/006

(57) ABSTRACT

A rotary drive mechanism comprises: a camshaft having a plurality of cams; and a plurality of transducer units each including a plurality of transducers that each have a dielectric elastomer layer and a pair of electrode layers sandwiching the dielectric elastomer layer. The plurality of transducer units each provide a drive force to a corresponding one of the plurality of cams. The plurality of transducers in one of the transducer units are arranged radially around the corresponding cam. Such a configuration can exert a drive force more efficiently.

### TECHNICAL FIELD

The present invention relates to a rotary drive mechanism.

### BACKGROUND ART

Patent Document 1, for example, discloses a drive mechanism using dielectric elastomer modules as actuators, where each of the dielectric elastomer modules has a dielectric elastomer layer and a pair of electrode layers sandwiching the dielectric elastomer layer. In the drive mechanism, a plurality of cam sections are arranged along the lengthwise direction of a shaft. The cam sections are connected to the respective dielectric elastomer modules. The dielectric elastomer modules are extended and contracted in a predetermined order to provide a rotational drive force for the shaft.

### PRIOR ART DOCUMENT

### Patent Document

Patent Document 1: JP-A-2014-507930

### SUMMARY OF THE INVENTION

### Problem to Be Solved by the Invention

In order to provide a stronger drive force for the shaft, more cam sections and dielectric elastomer modules need to be arranged along the lengthwise direction of the shaft. This causes the rotary drive mechanism to be too long.

The present invention has been conceived in view of the circumstances described above, and aims to provide a rotary drive mechanism capable of exerting a drive force efficiently.

### Means to Solve the Problem

A rotary drive mechanism provided by a first aspect of the present invention includes: a camshaft having a plurality of cams; and a plurality of transducer units each including a plurality of transducers that each have a dielectric elastomer layer and a pair of electrode layers sandwiching the dielectric elastomer layer. The plurality of transducer units each provide a drive force to a corresponding one of the plurality of cams. The plurality of transducers in one transducer unit are arranged radially around the corresponding cam.

In a preferred embodiment of the present invention, the plurality of cams have different diameters, and strokes of the plurality of transducer units are different from each other corresponding to the diameters of the respective cams.

In a preferred embodiment of the present invention, at least one of the plurality of transducer units is used for power generation.

A rotary drive mechanism provided by a second aspect of the present invention includes: a camshaft having a cam; a transducer unit including a plurality of transducers that each have a dielectric elastomer layer and a pair of electrode layers sandwiching the dielectric elastomer layer; and an electromagnetic motor connected to the camshaft. The transducer unit provides a drive force to the cam, and the plurality of transducers in the transducer unit are arranged radially around the cam.

### Advantages of the Invention

The present invention can provide a rotary drive mechanism capable of exerting a drive force more efficiently.

Other features and advantages of the present invention will be more apparent from the detailed description given below with reference to the accompanying drawings.

### BRIEF DESCRIPTION OF THE DRAWINGS

FIG. 1 is a perspective view showing a rotary drive mechanism according to a first embodiment of the present invention.

FIG. 2 is a cross-sectional view showing a transducer unit of the rotary drive mechanism according to the first embodiment of the present invention.

FIG. 3 is a perspective view showing a transducer of the rotary drive mechanism according to the first embodiment of the present invention.

FIG. 4 is a main-part enlarged cross-sectional view showing an example of the transducer of the rotary drive mechanism according to the first embodiment of the present invention.

FIG. 5 is a cross-sectional view along line V-V of FIG. 4, together with an inset showing a main-part enlarged cross-sectional view.

FIG. 6 is a cross-sectional view showing another example of the transducer of the rotary drive mechanism according to the first embodiment of the present invention, together with an inset of a main-part enlarged cross-sectional view.

FIG. 7 is a main-part enlarged cross-sectional view showing another example of the transducer of the rotary drive mechanism according to the first embodiment of the present invention.

FIG. 8 is a cross-sectional view along line VIII-VIII of FIG. 7.

FIG. 9 is a main-part enlarged cross-sectional view showing another example of the transducer of the rotary drive mechanism according to the first embodiment of the present invention.

FIG. 10 is a main-part enlarged cross-sectional view showing another example of the transducer of the rotary drive mechanism according to the first embodiment of the present invention.

FIG. 11 is a cross-sectional view showing another transducer unit of the rotary drive mechanism according to the first embodiment of the present invention.

FIG. 12 is a cross-sectional view showing another transducer unit of the rotary drive mechanism according to the first embodiment of the present invention.

FIG. 13 is a perspective view showing a rotary drive mechanism according to a second embodiment of the present invention.

FIG. 14 is a perspective view showing a rotary drive mechanism according to a third embodiment of the present invention.

FIG. 15 is a main-part enlarged cross-sectional view showing another example of the transducer of the rotary drive mechanism according to the present invention.

### MODE FOR CARRYING OUT THE INVENTION

The following describes preferred embodiments of the present invention with reference to the drawings.

### First Embodiment

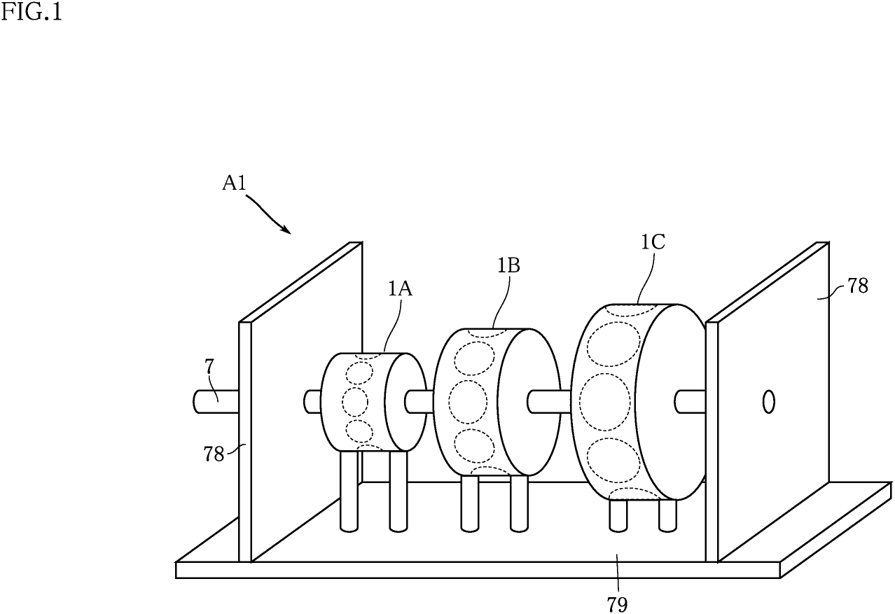

FIGS. 1 to 12 show a rotary drive mechanism according to a first embodiment of the present invention. A rotary drive mechanism A1 of the present embodiment includes a plurality of transducer units 1A, 1B, and 1C, and a camshaft 7. The rotary drive mechanism A1 outputs a rotational drive force from the camshaft 7.

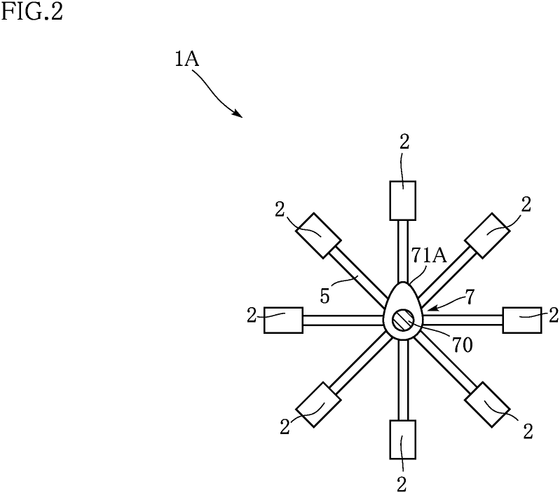

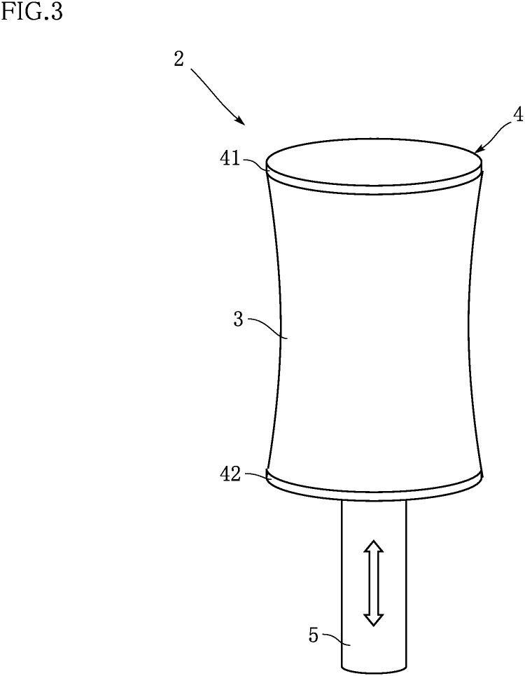

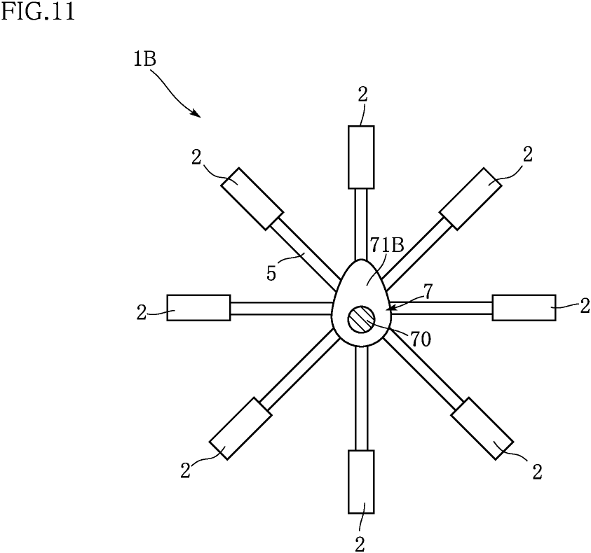

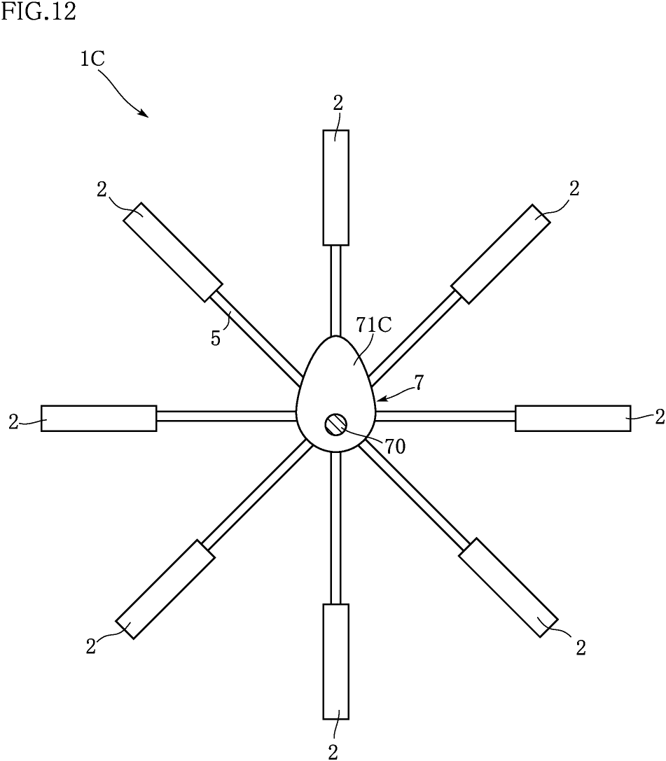

FIG. 1 is a perspective view showing the rotary drive mechanism A1. FIG. 2 is a cross-sectional view showing the transducer unit 1A. FIG. 3 is a perspective view and a main-part enlarged cross-sectional view showing a transducer 2 of the transducer unit 1A. FIG. 11 is a cross-sectional view showing the transducer unit 1B. FIG. 12 is a cross-sectional view showing the transducer unit 1C.

The cam shaft 7 includes a shaft 70 and a plurality of cams 71A, 71B, and 71C. The shaft 70 outputs, to the outside, a rotational drive force obtained by converting the drive force from each of the transducer units 1A, 1B, and 1C. In the present embodiment, portions of the shaft 70 near the ends thereof are rotatably supported by end plates 78. The end plates 78 are supported by a support plate 79, for example. The support structure with the end plates 78 and the support plate 79 is merely an example of the support structure of the shaft 70, and is not intended to limit the present invention.

Each of the cams 71A, 71B, and 71C converts a linear drive force from a corresponding one of the transducer units 1A, 1B, and 1C into a rotational drive force. The cams 71A, 71B, and 71C are arranged at intervals in the axial direction of the shaft 70, and are fixed to the shaft 70. Each of the cams 71A, 71B, and 71C has a shape where a radial dimension varies depending on a circumferential direction. In the state shown in FIGS. 2, 11, and 12, the radial dimension on the upper side of each of the FIGS. 2, 11, and 12 is the largest. The cams 71A, 71B, and 71C have different sizes. In the present embodiment, the cam 71A is the smallest, the cam 71C is the largest, and the cam 71B has a medium size.

Each of the transducer units 1A, 1B, and 1C has a plurality of transducers 2. The transducer unit 1A provides a drive force for the shaft 70 via the cam 71A. The transducer unit 1B provides a drive force for the shaft 70 via the cam 71B. The transducer unit 1C provides a drive force for the shaft 70 via the cam 71C.

As shown in FIG. 2, the transducer unit 1A has a plurality of transducers 2. The transducers 2 are arranged radially around the cam 71A. The number of transducers 2 is not particularly limited, and eight transducers 2 are used in the illustrated example. The transducers 2 of the transducer unit 1A are configured to exert a stroke corresponding to the difference between the maximum and minimum dimensions of the cam 71A in the radial direction.

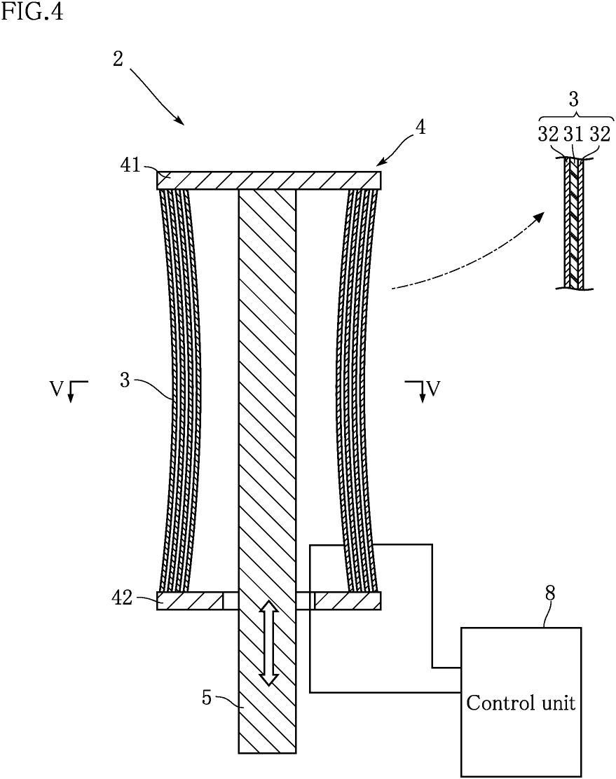

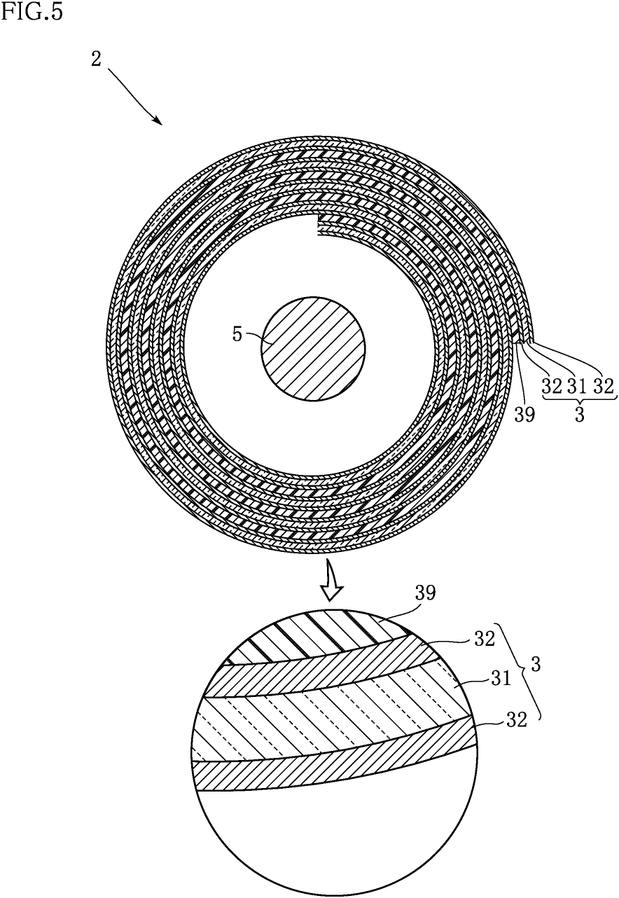

As shown in FIG. 3, each of the transducers 2 includes a dielectric elastomer element 3, a support 4, and a rod 5. As shown in FIG. 4, the dielectric elastomer element 3 includes a dielectric elastomer layer 31 and a pair of electrode layers 32. The dielectric elastomer element 3 is not limited to a particular configuration, and may have various configurations as long as the transducer 2 can function as an actuator or a power generation device. In the illustrated example, the dielectric elastomer element 3 is formed by winding a long rectangular raw material multiple times to form a cylindrical shape constituted by multiple layers as shown in FIG. 5. Furthermore, in the illustrated example, the dielectric elastomer element 3 is stacked on and wound together with an insulating layer 39. The insulating layer 39 is made of an insulating material such as an insulating resin or a material similar to the dielectric elastomer layer 31. The insulating layer 39 prevents electrical connection between adjacent portions of the electrode layers 32.

The dielectric elastomer layer 31 is required to be elastically deformable and to have high insulating strength. Although the material of the dielectric elastomer layer 31 is not particularly limited, preferable examples include silicone elastomer, acrylic elastomer, and styrene elastomer.

The pair of electrode layers 32 are layers that sandwich the dielectric elastomer layer 31, and to which a voltage is applied. The electrode layers 32 are made of a material that has conductivity and is elastically deformable following the elastic deformation of the dielectric elastomer layer 31. Such a material may be obtained by mixing an elastically deformable main material with a filler that provides conductivity. The filler may preferably be a carbon nanotube, for example.

The support 4 is a supporting structure that supports the dielectric elastomer element 3 in a desired state. The support 4 of the transducer unit 1A includes support discs 41 and 42. The support discs 41 and 42 are preferably made of an insulating material such as resin. The support discs 41 and 42 are fixed to the respective ends of the dielectric elastomer element 3 that is wound into a cylindrical shape. In the example shown in FIG. 4, the support disc 42 is provided with a through-hole and supported by a non-illustrated fixed member (e.g., a member fixed to the support plate 79). The rod 5 is inserted in the through hole of the support disc 42. The rod 5 is fixed to the support disc 41, and is movable relative to the support disc 42.

In the initial state of the present example, the support disc 41 is moved away from the support disc 42 by the rod 5. As a result, the dielectric elastomer element 3 is pulled in the axial direction to generate tension. The reacting force to the tension serves as a force that pushes the rod 5 to the camshaft 7.

The rod 5 transmits the drive force exerted by the dielectric elastomer element 3 to the cam 71A. In the illustrated example, the rod 5 has one end fixed to the support disc 41 and the other end in contact with the cam 71A.

FIGS. 3 and 4 show the dielectric elastomer element 3 under vertical tension. Due to the tension, the cylindrical dielectric elastomer element 3 has an hourglass shape where the middle portion of the dielectric elastomer element 3 in the vertical direction has a smaller diameter than each end of the dielectric elastomer element 3.

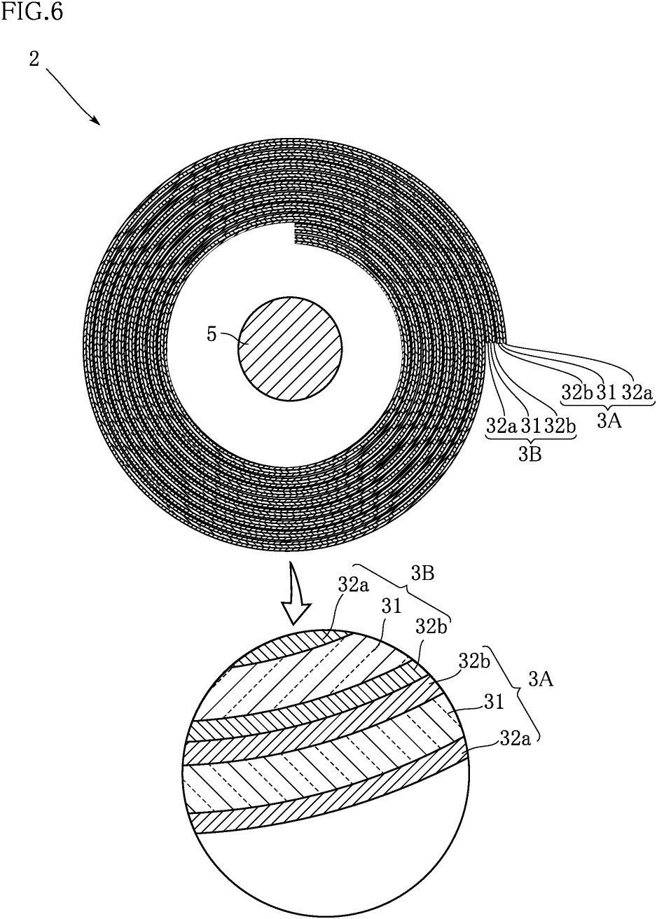

FIG. 6 shows another example of the transducer 2. In the illustrated example, two dielectric elastomer elements 3A and 3B are stacked and wound together. The dielectric elastomer element 3A includes electrode layers 32a and 32b. The dielectric elastomer element 3B includes electrode layers 32a and 32b. The electrode layer 32b of the dielectric elastomer element 3A and the electrode layer 32b of the dielectric elastomer element 3B face each other and are in contact with each other. Furthermore, in the state where the two dielectric elastomer elements 3A and 3B are wound, the electrode layer 32a of the dielectric elastomer element 3B and the electrode layer 32a of the dielectric elastomer element 3A that is adjacent to the inner side of the electrode layer 32a of the dielectric elastomer element 3B face each other and are in contact with each other. In the present example, it is preferable that each of the electrode layers 32a be set to a ground potential.

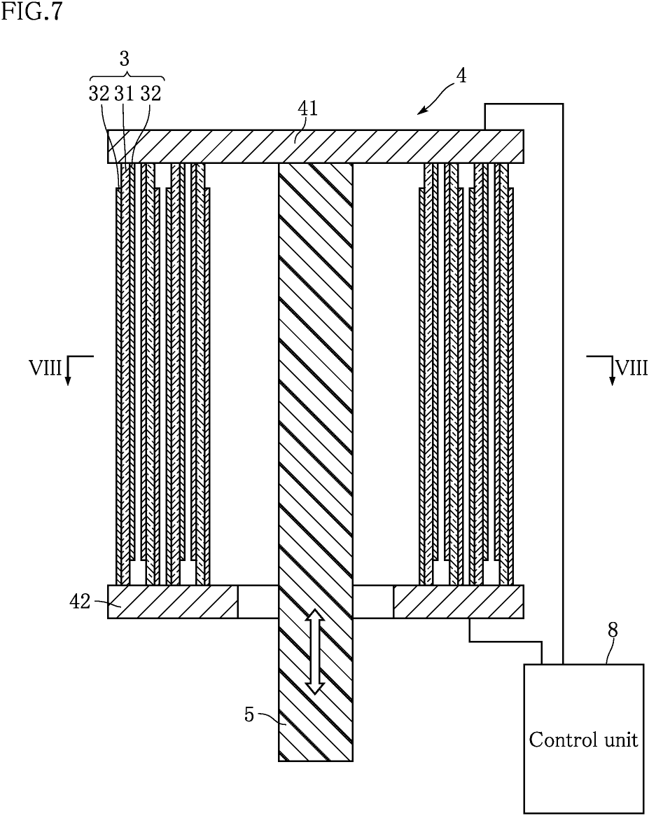

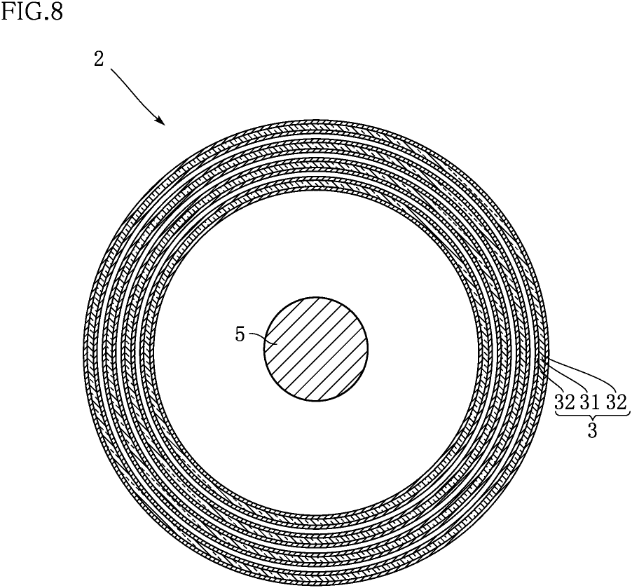

FIGS. 7 and 8 show another example of the transducer 2. In the illustrated example, a plurality of dielectric elastomer elements 3 are arranged concentrically. In other words, each of the dielectric elastomer elements 3 has a cylindrical shape. The dielectric elastomer elements 3, each of which has a cylindrical shape, are nested to form concentric circles. In the present example, the dielectric elastomer element 3 under tension forms an hourglass shape, as with the example shown in FIGS. 3 and 4. For convenience of understanding, FIG. 7 shows a non-constricted state.

In the present example, the support discs 41 and 42 are used as conductive members for energizing the electrode layers 32. In the present example, each of the support discs 41 and 42 includes a conductive material such as metal. For example, each of the support discs 41 and 42 may be a wiring board having an insulating base member made of, for example, glass epoxy resin, and a wiring pattern formed on the base member. Alternatively, each of the support discs 41 and 42 may be entirely made of a metal material. For convenience of understanding, FIG. 7 shows the rod 5 and the support discs 41 and 42 with different hatchings. This means that when the rod 5 is made of an insulating material, for example, or when a member made of an insulating material is provided between the support discs 41 and 42, the support discs 41 and 42 are insulated from each other.

As shown in FIG. 7, the outer electrode layer 32 of the outermost dielectric elastomer element 3 is in contact with the support disc 42 and is electrically connected to the support disc 42. On the other hand, the inner electrode layer 32 of the dielectric elastomer element 3 is in contact with the support disc 41 and is electrically connected to the support disc 41. Among the electrode layers 32 of two adjacent dielectric elastomer elements 3, the pair of electrode layers 32 that are opposed to each other are in contact with only one support disc from among the support discs 41 and 42 and are electrically connected to the only one support disc. With such a configuration, there is no need to connect wires from a control unit 8 to all of the dielectric elastomer elements 3, and it is only necessary to connect the wires to the support discs 41 and 42. This makes it possible to improve the manufacturing efficiency of the transducers 2.

The rotary drive mechanism A1 includes the control unit 8. The control unit 8 controls the drive of the transducer units 1A, 1B, and 1C. The control unit 8 performs control for causing the transducer units 1A, 1B, and 1C to function as actuators. The control unit 8 also performs control for causing the transducer units 1A, 1B, and 1C to function as power generation devices. The control unit 8 is connected to each of the transducers 2 of the transducer units 1A, 1B, and 1C. The control unit 8 has, for example, a sensor that detects the rotational position of the shaft 70 (the rotational positions of the cams 71A, 71B, and 71C) .

In the case where the control unit 8 causes the transducer units 1A, 1B, and 1C to function as actuators, the control unit 8 includes a power supply circuit. The power supply circuit applies a voltage to create a potential difference between the pair of dielectric elastomer layers 31 of each transducer 2. The dielectric elastomer layer 31 becomes thinner in response to the potential difference. The extension of the dielectric elastomer element 3 is controlled by the control of the voltage application, whereby the drive of the transducer 2 is controlled.

In the case where the control unit 8 causes the transducer units 1A, 1B, and 1C to function as power generation devices, the control unit 8 includes a power supply circuit for applying an initial voltage, a switch circuit, a storage circuit for storing electric charge from the transducers 2, and so on, as appropriate. The power supply circuit applies a voltage for putting a predetermined amount of charge on the pair of dielectric elastomer layers 31 at the initial stage of power generation. The switch circuit appropriately switches the connection state between the pair of dielectric elastomer layers 31 and each of the power supply circuit and the storage circuit. The storage circuit stores the charge built up by the extension and contraction of the dielectric elastomer elements 3 in the transducers 2.

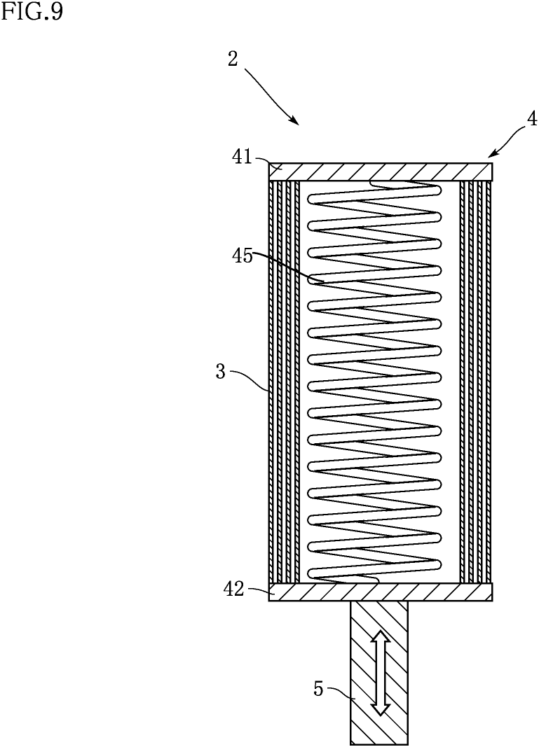

FIG. 9 shows another example of the transducer 2. In the present example, a spring 45 is provided between the support disc 41 and the support disc 42. The support disc 41 is fixed to a non-illustrated fixed portion (e.g., a portion fixed to the support plate 79). The spring 45 is longer than the axial length (i.e., vertical length in the figure) of the dielectric elastomer element 3 in its natural state. Accordingly, when the dielectric elastomer element 3 and the spring 45 are attached to the support discs 41 and 42, the spring 45 is compressed, and the dielectric elastomer element 3 is pulled as a result. When the dielectric elastomer element 3 is given an electric potential and extended by the control of the control unit 8, the restraint of the spring 45 by the dielectric elastomer element 3 is weakened. The force corresponding to the amount being weakened serves as a force that pushes the rod 5 to the camshaft 7. In the present example, when the dielectric elastomer element 3 is under tension, the contraction at the middle portion of the dielectric elastomer element 3 in the vertical direction is regulated by the spring 45. Accordingly, the dielectric elastomer element 3 in the present example is less constricted or almost not constricted at the middle portion as compared to the above example without the spring 45.

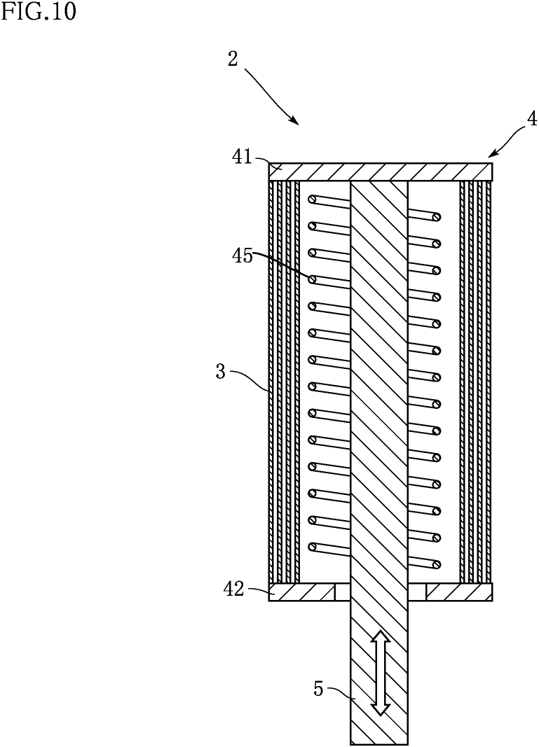

FIG. 10 shows another example of the transducer 2. The rod 5 is inserted into the spring 45. The support disc 42 is fixed to a non-illustrated fixed portion (e.g., a portion fixed to the support plate 79) . When the dielectric elastomer element 3 is given an electric potential and extended, the spring 45 is extended to pull the rod 5 upward in the figure. On the other hand, when the electric potential given to the dielectric elastomer element 3 is removed, the dielectric elastomer layer 31 of the dielectric elastomer element 3 is contracted to cause the spring 45 to be also contracted. This generates the force that pushes the rod 5 to the camshaft 7.

As shown in FIG. 11, the transducer unit 1B has a plurality of transducers 2. The transducers 2 are arranged radially around the cam 71B. The number of transducers 2 is not particularly limited, and eight transducers 2 are used in the illustrated example. The transducers 2 of the transducer unit 1B are configured to exert a stroke corresponding to the difference between the maximum and minimum dimensions of the cam 71B in the radial direction, where the stroke is larger than the stroke exerted by the transducers 2 of the transducer unit 1A.

As shown in FIG. 12, the transducer unit 1C has a plurality of transducers 2. The transducers 2 are arranged radially around the cam 71C. The number of transducers 2 is not particularly limited, and eight transducers 2 are used in the illustrated example. The transducers 2 of the transducer unit 1C are configured to exert a stroke corresponding to the difference between the maximum and minimum dimensions of the cam 71C in the radial direction, where the stroke is larger than the stroke exerted by the transducers 2 of each of the transducer units 1A and 1B.

When the transducers 2 shown in FIGS. 3 to 9 are used for the transducer units 1A, 1B, and 1C, the transducers 2 with the shortest stroke are selected as those of the transducer unit 1A, the transducers 2 with the longest stroke are selected as those of the transducer unit 1C, and the transducers 2 with a medium-length stroke is selected as those of the transducer unit 1B.

The rotary drive mechanism A1 is driven to rotate by the control unit 8 applying a voltage to each of the transducer units 1A, 1B, and 1C. The voltage application by the control unit 8 is synchronously controlled with the rotational position of the shaft 70 (cams 71A, 71B, and 71C). In other words, in each of the transducer units 1A, 1B, and 1C, the transducer 2 corresponding to the portion having the largest diameter of the cams 71A, 71B, and 71C may provide a force in the direction to push the cams 71A, 71B, and 71C, respectively. The radially arranged transducers 2 sequentially provide this force so that the rotational force for each of the cams 71A, 71B, and 71C is provided in succession, resulting in the rotational drive force being outputted from the shaft 70.

The transducer units 1A, 1B, and 1C may be used in a mode where the same voltage application control is performed for all of the transducer units 1A, 1B, and 1C or, alternatively, may be used in a mode where the voltage application control is performed at different timings for the transducer units 1A, 1B, and 1C. As the mode where the voltage application control is performed at different timings, one can imagine a case where a larger torque is required to start rotation in the initial drive period when the rotary drive mechanism A1 starts rotating. In this case, the transducer unit 1C with a relatively large stroke is used to rotatably drive the shaft 70. When the rotational speed of the shaft 70 reaches a first predetermined speed, the transducer unit 1B with the second largest stroke is used to rotatably drive the shaft 70. When the rotational speed of the shaft 70 reaches a second predetermined speed that is faster, the transducer unit 1C with the smallest stroke is used to rotatably drive the shaft 70.

When, unlike the initial drive start period, the rotational speed of a device or the like that uses the rotary drive mechanism A1 is to be decreased, any or all of the transducer units 1A, 1B, and 1C may be used as a power generation device.

Next, the operation of the rotary drive mechanism A1 will be described.

According to the present embodiment, the transducers 2 of each of the transducer units 1A, 1B, and 1C are arranged radially around a corresponding one of the cams 71A, 71B, and 71C of the camshaft 7. This makes it possible to obtain a larger rotational drive force by utilizing the drive force of the transducers 2. It is also possible to prevent the sizes of the transducer units 1A, 1B, and 1C in the axial direction of the shaft 70 from becoming too large due to the arrangement of the transducers 2. As such, a drive force can be exerted more efficiently.

With the transducer units 1A, 1B, and 1C with different strokes, the rotary drive mechanism A1 can selectively use the transducer units 1A, 1B, and 1C according to the magnitude of a required torque. This makes it possible to further improve the efficiency of the rotational drive of the rotary drive mechanism A1.

The transducers 2 that use the dielectric elastomer elements 3 can be used as power generation devices as well as actuators. Accordingly, when a device or the like that is rotatably driven by the rotary drive mechanism A1 needs deliberate deceleration, the rotational kinetic energy for the device can be collected as electric energy from any or all of the transducer units 1A, 1B, and 1C. This makes it possible to further improve the energy efficiency of the rotary drive mechanism A1.

Although the rotary drive mechanism A1 uses the transducer units 1A, 1B, and 1C with different strokes, it may use transducer units 1A, 1B, and 1C with the same stroke instead. Such an alternative configuration also enables higher output with the transducer units 1A, 1B, and 1C and higher efficiency through power generation by any or all of the transducer units 1A, 1B, and 1C.

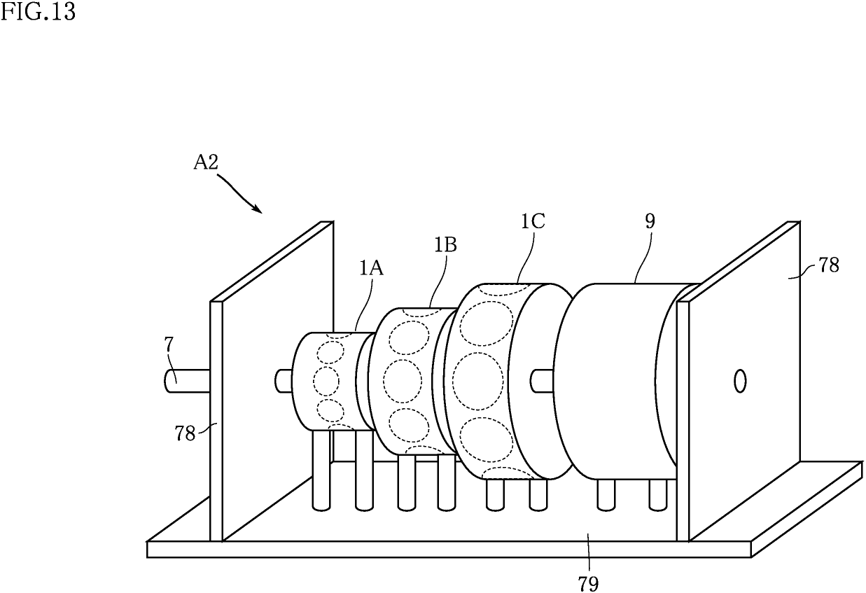

FIGS. 13 to 15 show other embodiments of the present invention. In these figures, elements identical or similar to the above embodiment are provided with the same reference signs as those in the above embodiment.

### Second Embodiment

FIG. 13 shows a rotary drive mechanism according to a second embodiment of the present invention. A rotary drive mechanism A2 of the present embodiment includes an electromagnetic motor 9 in addition to the transducer units 1A, 1B, and 1C.

In the present embodiment, the transducer units 1A, 1B, and 1C are also similarly attached to the respective cams 71A, 71B, and 17C of the camshaft 7. The electromagnetic motor 9 is attached to the shaft 70.

The electromagnetic motor 9 is used as a drive source that rotatably drives the shaft 70 together with or prior to the transducer unit 1C during the initial drive start period of the rotary drive mechanism A2, for example. For example, a motor capable of generating a torque larger than the torque generated by the transducer unit 1C may be selected as the electromagnetic motor 9, so that a drive force can be generated more quickly at the start of driving the rotary drive mechanism A2. The electromagnetic motor 9 can be used not only as a drive source but also as a power generation device as appropriate.

### Third Embodiment

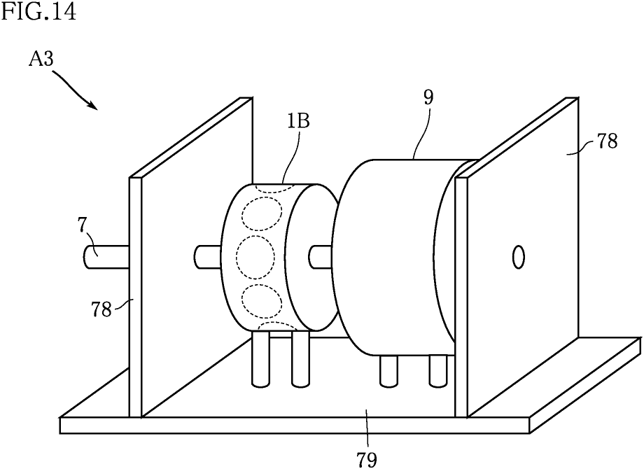

FIG. 14 shows a rotary drive mechanism according to a third embodiment of the present invention. A rotary drive mechanism A3 of the present embodiment includes a single transducer unit 1B and an electromagnetic motor 9.

The transducer unit 1B may be used as an actuator for generating a rotational drive force or as a power generation device as described above. The electromagnetic motor 9 may be used as a drive source for rotational drive or as a power generation device. As can be understood from the present embodiment, the concept of the rotary drive mechanism according to the present invention includes a configuration with the transducer unit 1B and the electromagnetic motor 9, in addition to a configuration with the transducer units 1A, 1B, and 1C.

### Variation of Transducers 2

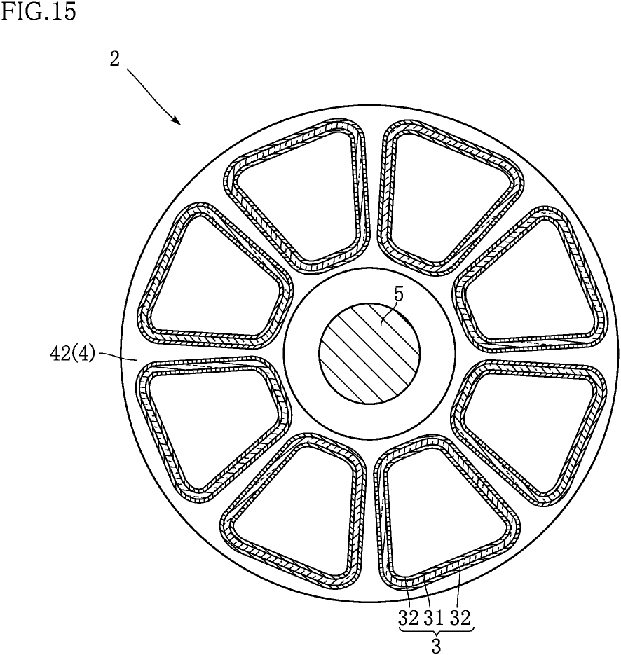

FIG. 15 shows another example of the transducers 2. FIG. 15 shows the portion of each of the dielectric elastomer elements 3 that is attached to the support disc 42. In the present example, the dielectric elastomer elements 3 are not arranged concentrically. Instead, the dielectric elastomer elements 3 are arranged to overlap with the support discs 41 and 42 as viewed in the direction in which the rod 5 extends (i.e., the direction in which the support discs 41 and 42 are spaced apart from each other). Furthermore, in the illustrated example, the dielectric elastomer elements 3 surround the rod 5 with the rod 5 at the center. The dielectric elastomer elements 3 are arranged around the rod 5 in a single row along the circumference of the rod 5. The dielectric elastomer elements 3 are not limited to the single-row arrangement. The dielectric elastomer elements 3 may be arranged in multiple rows or in a staggered pattern along the circumference direction.

Although each of the dielectric elastomer elements 3 forms a single-layer annulus for convenience, the present disclosure is not limited to this. Each of the dielectric elastomer elements 3 may form multiple layers as described in the above example. The portion of each of the dielectric elastomer elements 3 that is attached to the support disc 42 is not limited to a particular shape. In the illustrated example, said portion has a substantially trapezoidal shape. The height direction of the trapezoid substantially coincides with the radial direction of the transducer 2. The upper base of the trapezoid is positioned inward in the radial direction, and the lower base of the trapezoid is positioned outward in the radial direction. The same applies to the portion of each of the dielectric elastomer elements 3 that is attached to the support disc 41. In the case where the portions of each of the dielectric elastomer elements 3 that are attached to the support discs 41 and 42 are each designed to have, for example, a trapezoidal shape, members (not illustrated) having the corresponding shape may be attached to the support discs 41 and 42 so that the portions of each of the dielectric elastomer elements 3 can be made to have the trapezoidal shape.

The example as given above can increase the weight and surface area of each of the dielectric elastomer elements 3 (dielectric elastomer layers 31) in the transducer 2. This is advantageous for higher output when the transducer 2 is used as an actuator. Furthermore, when the portions of the dielectric elastomer elements 3 that are attached to the support discs 41 and 42 are each designed to have a trapezoidal shape, the arrangement density of the dielectric elastomer elements 3 can be further increased. It is preferable that the outer electrode layer 32 of each of the dielectric elastomer elements 3 be set to a ground potential. This allows contact between the electrode layers 32 of adjacent dielectric elastomer elements 3, and can bring the dielectric elastomer elements 3 close to each other.

The rotary drive mechanism according to the present invention is not limited to the foregoing embodiments. Various modifications can be made to the specific configurations of the elements of the rotary drive mechanism of the present invention.

1. A rotary drive mechanism, comprising:
a camshaft having a plurality of cams; and
a plurality of transducer units each including a plurality of transducers that each have a dielectric elastomer layer and a pair of electrode layers sandwiching the dielectric elastomer layer,
wherein the plurality of transducer units each provide a drive force to a corresponding one of the plurality of cams, and
the plurality of transducers in one transducer unit from among the transducer units are arranged radially around the corresponding cam.

2. The rotary drive mechanism according to claim 1,
wherein the plurality of cams have different diameters, and
strokes of the plurality of transducer units are different from each other corresponding to the diameters of the respective cams.

3. The rotary drive mechanism according to claim 1, wherein at least one of the plurality of transducer units is used for power generation.

4. A rotary drive mechanism, comprising:
a camshaft having a cam;
a transducer unit including a plurality of transducers that each have a dielectric elastomer layer and a pair of electrode layers sandwiching the dielectric elastomer layer; and
an electromagnetic motor connected to the camshaft,
wherein the transducer unit provides a drive force to the cam, and
the plurality of transducers in the transducer unit are arranged radially around the cam.

5. The rotary drive mechanism according to claim 2, wherein at least one of the plurality of transducer units is used for power generation.
